(19) United States
(12) Patent Application Publication
(10) Pub. No.: US 2015/0129915 A1
(43) Pub. Date: May 14, 2015

(54) LIGHT-EMITTING DIODE PROVIDED WITH SUBSTRATE HAVING PATTERN ON REAR SIDE THEREOF, AND METHOD FOR MANUFACTURING SAME

(71) Applicant: Seoul Viosys Co., Ltd., Ansan-si (KR)

(72) Inventors: ChungHoon Lee, Ansan-si (KR); DaeSung Cho, Ansan-si (KR); KiBum Nam, Ansan-si (KR)

(73) Assignee: Seoul Viosys Co., Ltd., Ansan-si (KR)

(21) Appl. No.: 14/395,470

(22) PCT Filed: Apr. 15, 2013
(86) PCT No.: PCT/KR2013/003127

§ 371 Date: Oct. 17, 2014

(30) Foreign Application Priority Data
Apr. 18, 2012 (KR) 1020120040098

(51) Int. Cl. H01L 33/20; H01L 33/46; H01L 33/00; H01L 33/50

(52) U.S. Cl. CPC H01L 33/20; H01L 33/505; H01L 33/46; H01L 33/0075; H01L 2933/0025; H01L 2933/0041; H01L 2933/0033
USPC 257/98; 438/33; 438/29

(57) ABSTRACT

A method for manufacturing a light-emitting diode is provided. First, a substrate having a front or top surface and a rear or bottom surface is provided. An uneven pattern is formed on the rear or bottom surface. A light-emitting semiconductor layer is formed by stacking a first semiconductor layer, an active layer, and a second semiconductor layer on the front or top surface of the substrate having the uneven pattern. The light-emitting semiconductor layer and the substrate are separated into a plurality of light-emitting cells.

### BACKGROUND

1. Field of the Invention

This patent document relates to a semiconductor device including a light-emitting diode.

2. Discussion of Related Art

A light-emitting diode is a device including an n-type semiconductor layer, a p-type semiconductor layer, and an active layer interposed between the n-type semiconductor layer and the p-type semiconductor layer. When an electric field is applied to the n-type and p-type semiconductor layers in a forward direction, electrons and holes are injected into the active layer, and the electrons and holes injected into the active layer are recombined to emit light.

Efficiency of the light-emitting diode depends on internal quantum efficiency and light extraction efficiency, that is, external quantum efficiency. In order to improve the light extraction efficiency, uneven patterns can be formed on a substrate to provide a patterned substrate, for example, a patterned sapphire substrate (PSS), and then a semiconductor layer can be grown on the uneven pattern of the patterned substrate. However, the light extraction efficiency remaining low is a continuing issue.

### SUMMARY OF THE INVENTION

Embodiments of this patent document provide a light-emitting diode having improved light-emitting efficiency, and a method of fabricating the same.

According to an aspect of this patent document, there is provided a method of fabricating a light-emitting diode. First, a substrate having a front or top surface and a rear or bottom surface is provided. Uneven patterns are formed in the rear or bottom surface. A light-emitting semiconductor layer is formed by stacking a first-type semiconductor layer, an active layer, and a second-type semiconductor layer over the front or top surface of the substrate having the uneven patterns in the rear or bottom surface. The light-emitting semiconductor layer and the substrate are separated into a plurality of light-emitting cells.

In some embodiments, the substrate has a plurality of light-emitting cell regions and a separating area located between the light-emitting cell regions, and the forming of the uneven patterns may include forming a separating trench whose inlet width is greater than a bottom width of the trench in the separating area and areas adjacent to the separating area, and forming the uneven patterns in the light-emitting cell regions.

As an example, before the forming of the separating trench, a first mask pattern exposing the separating area and the areas adjacent to the separating areas may be formed on the rear or bottom surface of the substrate, and the separating area in which the separating trench is to be formed may be laser-scribed. At this time, the forming of the separating trench may include wet-etching on the rear or bottom surface of the laser-scribed substrate using the first mask pattern as a mask. Next, a second mask pattern may be formed to fill the separating trench. The forming of the uneven pattern includes wet-etching on the rear or bottom surface of the substrate using the second mask pattern as a mask. In some implementations, the second mask pattern may be formed to fill the separating trench and expose portions of each light-emitting cell region, and the forming of the uneven pattern may include dry-etching on the rear or bottom surface of the substrate using the second mask pattern as a mask.

In some implementations, the separating area may be laser-scribed before forming the separating trench, and the forming of the separating trenches and the forming of the uneven pattern may be simultaneously performed by wet-etching of the rear or bottom surface of the laser-scribed substrate.

In some implementations, a fluorescent material layer may be formed on the uneven pattern before separating the light-emitting semiconductor layer and the substrate into the plurality of light-emitting cells.

In some implementations, before forming the uneven patterns, a first mask pattern may be formed on the separating area and the areas adjacent to the separating areas and a trench may be formed in the rear or bottom surface by etching the rear or bottom surface using the first mask pattern as a mask. In some implementations, the uneven patterns may be formed in a bottom surface of the trench. In some implementation, a reflective layer may be further formed on the uneven pattern before separating the light-emitting semiconductor layer and the substrate into the plurality of light-emitting cells.

According to another aspect of the this patent document, there is provided a light-emitting diode to include a substrate having a front or top surface and a rear or bottom surface, uneven patterns formed in the rear or bottom surface of the substrate, and a first-type semiconductor layer, an active layer, and a second-type semiconductor layer stacked on the front or top surface of the substrate.

In some implementations, a sidewall of the substrate may include an inclined surface such that the substrate has a smaller width at the rear or bottom surface than the front or top surface. In some implementations, a fluorescent material layer may be disposed on the uneven patterns.

In some implementations, the substrate may include a trench in the rear or bottom surface, and the uneven patterns may be located in a bottom surface of the trench. In some implementations, a reflective layer may be disposed on the uneven patterns.

### BRIEF DESCRIPTION OF DRAWINGS

FIGS. 1A to 1G are cross-sectional views showing a method of fabricating a light-emitting diode according to an embodiment of this patent document.

FIG. 2 is a cross-sectional view showing a package of the light-emitting diode chip described with reference to FIGS. 1A to 1G.

FIGS. 3A to 3C are cross-sectional views showing a method of fabricating a light-emitting diode according to another embodiment of the disclosed technology.

FIGS. 4A and 4B are cross-sectional views showing a method of fabricating a light-emitting diode according to another embodiment of the disclosed technology.

FIGS. 5A to 5E are cross-sectional views showing a method of fabricating a light-emitting diode according to another embodiment of the disclosed technology.

### DETAILED DESCRIPTION OF EXEMPLARY EMBODIMENTS

Exemplary embodiments of this patent document will be described in detail below with reference to the accompanying drawings. The embodiments of this patent document may, however, be modified in different forms and should not be construed as limited to the embodiments set forth herein.

It will be understood that when a layer is referred to as being “on” another layer or a substrate, the layer may be formed directly on the other layer or the substrate, or an intervening layer may exist between the layer and the other layer or the substrate. Furthermore, the terms “upper,” “upper portion,” “upper surface,” or the like may be understood as “lower,” “lower portion,” or “lower surface,” or the like. That is, spatially relative terms are intended to encompass different orientations, that is, they are relative only and not intended to imply an absolute direction. It will be understood that, although the terms “first,” “second,” etc. may be used herein to describe various elements, these elements should not be limited by these terms. These terms are only used to distinguish one element from another.

In addition, in the drawings, some aspects of certain components, e.g., the thicknesses of layers or regions may be exaggerated for clarity. Like numerals refer to like elements throughout the description of the figures.

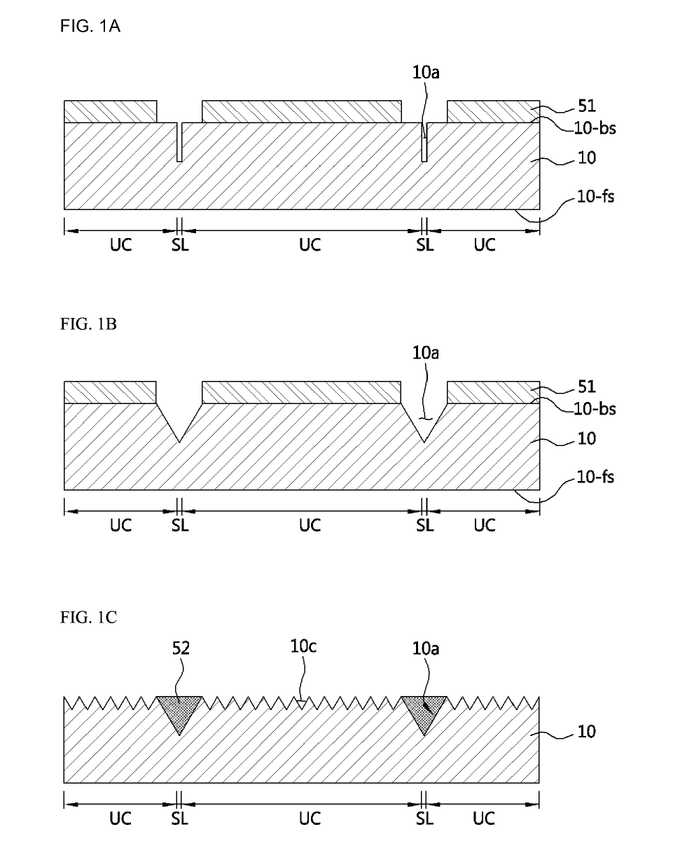

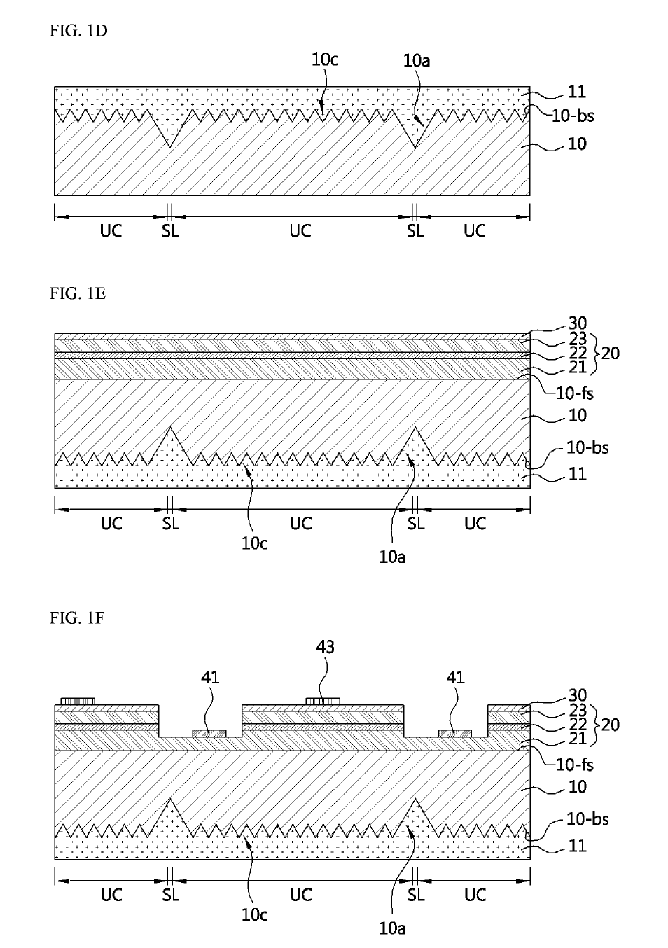

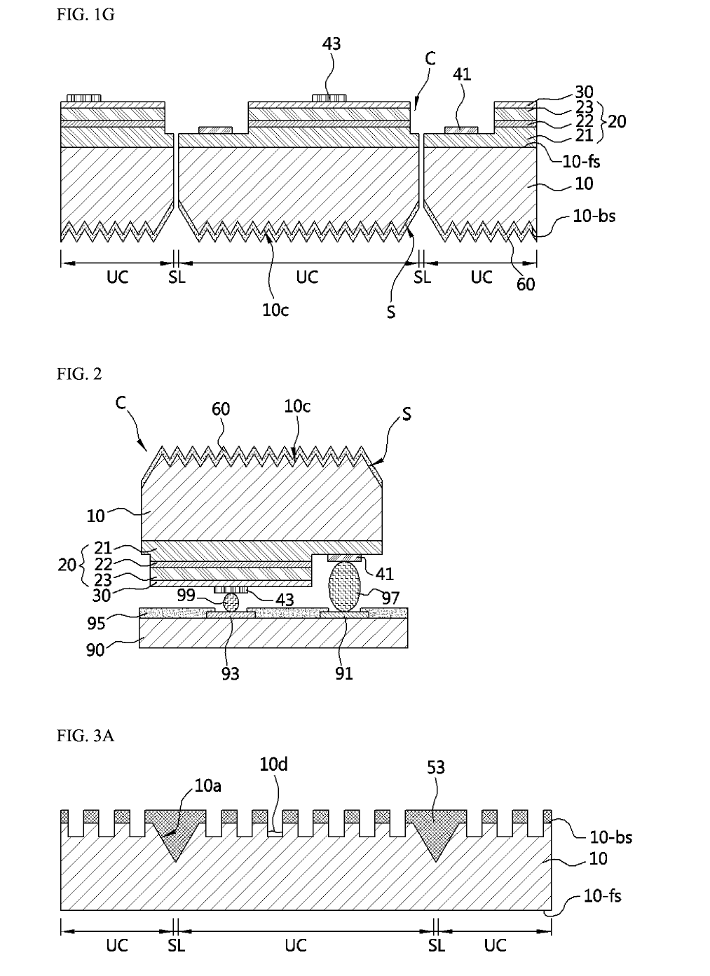

FIGS. 1A to 1G are cross-sectional views showing a method of fabricating a light-emitting diode according to an embodiment of this patent document.

Referring to FIG. 1A, a substrate 10 is provided. The substrate 10 may be sapphire (Al₂O₃), silicon carbide (SiC), gallium nitride (GaN), indium gallium nitride (InGaN), aluminum gallium nitride (AlGaN), aluminum nitride (AlN), gallium oxide (Ga₂O₃), or a silicon substrate. For example, the substrate 10 may be a nitride semiconductor substrate, for example, a GaN substrate. The substrate 10 includes light-emitting cell regions UC and separating areas SL located between light-emitting cell regions UC. In addition, the substrate 10 includes a front or top surface 10_fs and a rear or bottom surface 10_bs.

A first mask pattern 51 may be formed on the rear or bottom surface 10_bs. When the substrate 10 is, for example, a nitride semiconductor substrate such as a GaN substrate, the rear or bottom surface 10_bs may have an N-face. The first mask pattern 51 may be or include a photoresist pattern. The first mask pattern 51 may expose the separating areas SL and portions of light-emitting cell regions UC, which are adjacent to the separating areas SL. Separating trenches 10a may be formed in the separating areas SL exposed by the first mask pattern 51. The formation of the separating trenches 10a may be performed using a laser scribing method. In one example, widths of inlets and bottoms of the separating trenches 10a may be substantially the same.

Referring to FIG. 1B, a wet-etching solution may be applied to the rear or bottom surface 10_bs of the substrate 10 in which the separating trenches 10a are formed. As a result, the rear or bottom surface 10_bs of the substrate may be wet-etched by using the first mask pattern 51 as an etch mask. In this process, since side surfaces of the separating trenches 10a are primarily etched compared to bottom surfaces of the separating trenches 10a, the separating trenches 10a may have a V-shape whose inlet width is greater than a bottom width of the separating trenches 10a. The wet-etching solution may be or include a sulfate-phosphate mixed solution or a KOH solution. The wet-etching solution may be or include a heated solution.

Referring to FIG. 1C, the first mask pattern 51 may be removed. Next, a second mask pattern 52 filling the separating trenches 10a may be formed. The second mask pattern 52 may expose the light-emitting cell regions UC between the separating trenches 10a. The second mask pattern 52 may be or include a photoresist pattern. The second mask pattern 52 may be formed by forming a photoresist layer (not shown) filling the separating trenches 10a on the rear or bottom surface 10_bs of the substrate 10 where the first mask pattern 51 has been removed, and etching back the photoresist layer.

A wet-etching solution may be applied to the rear or bottom surface 10_bs of the substrate 10 in which the light-emitting cell regions UC are exposed. As a result, the rear or bottom surface 10_bs of the substrate 10 may be wet-etched by using the second mask pattern 52 as an etch mask to form uneven patterns such as concave-convex patterns 10c in the light-emitting cell regions UC. Concave portions of the uneven patterns 10c may have a V-shape. The wet-etching solution may be or include a sulfate-phosphate mixed solution or a KOH solution. The wet-etching solution may be or include a heated solution. Referring to FIG. 1D, the second mask pattern 52 may be removed, and an insulating layer 11 may be formed on the rear or bottom surface 10_bs of the substrate 10. The insulating layer 11 may be or include a silicon oxide layer. The insulating layer 11 may fully fill the separating trenches 10a and the concave portions of the uneven patterns 10c, and upper surface of the insulating layer 11 may be substantially flat

Referring to FIG. 1E, a first conductivity-type semiconductor layer 21, an active layer 22, and a second conductivity-type semiconductor layer 23 may be formed on the front or top surface 10_fs of the substrate 10. In this case, on the rear or bottom surface 10_bs of the substrate 10, the insulating layer 11 is formed. The first conductivity-type semiconductor layer 21, the active layer 22, and the second conductivity-type semiconductor layer 23 may form a light-emitting semiconductor layer 20.

The first conductivity-type semiconductor layer 21 may be or include a nitride-based semiconductor layer doped with an n-type dopant. For example, the first conductivity-type semiconductor layer 21 may be or include an InₓAl_{y}Ga_{1-x-y}N (0≦x≦1, 0≦y≦1, and x+y≦1) layer doped with Si as the n-type dopant. The active layer 22 may be or include an InₓAl_{y}Ga_{1-x-y}N (0≦x≦1, 0≦y≦1, and 0≦x+y≦1) layer, and have a single quantum well (SQW) structure or a multi-quantum well (MQW) structure. The second conductivity-type semiconductor layer 23 may be or include a nitride-based semiconductor layer doped with p-type dopant. For example, the second conductivity-type semiconductor layer 23 may be or include an InₓAl_{y}Ga_{1-x-y}N (0≦x≦1, 0≦y≦1, and 0≦x+y≦1) layer doped with Mg or Zn as a p-type dopant. The light-emitting semiconductor layer 20 may be formed by an MOCVD (metal organic chemical vapor deposition) method or an MBE (molecular beam epitaxy) method layer 20. The current spreading conductive layer 30 may be or include a transparent conductive layer such as an indium tin oxide (ITO) layer.

During the formation of the light-emitting semiconductor layer 20, the semiconductor layer may not be grown on the rear or bottom surface 10_bs of the substrate 10 due to the insulating layer 11. In addition, the insulating layer 11 allows the substrate 10 to stably maintain horizontal balance in a chamber in which the light-emitting semiconductor layer 20 and the current spreading conductive layer 30 are formed. Thus, heat can be uniformly distributed over the entire substrate 10 during the formation of the light-emitting semiconductor layer 20, and thus, variations can be reduced in growth of the light-emitting semiconductor layer 20.

Referring to FIG. 1F, the current spreading conductive layer 30, the second conductivity-type semiconductor layer 23, and the active layer 22 are mesa-etched to expose the first conductivity-type semiconductor layer 21. As the result of the mesa-etching, portions of the first conductive-type semiconductor layer 21 may be exposed. A first electrode 41 and a second electrode 43 may be formed on the exposed portions of the first conductivity-type semiconductor layer 21 and current spreading conductive layer 30, respectively.

Referring to FIG. 1g, the insulating layer 11 may be removed using wet or dry etching. Then, a fluorescent layer 60 may be formed on the rear or bottom surface 10_bs of the substrate 10 from which the insulating layer 11 is removed. Next, the separating areas SL are scribed and cut to provide separated light-emitting cells. Each of the light-emitting cells may form a light-emitting diode chip C.

FIG. 2 is a cross-sectional view showing a package of the light-emitting diode chip described with reference to FIGS. 1A to 1G.

Referring to FIG. 2, a package substrate 90 is provided. The package substrate 90 may be or include a ceramic substrate or a resin substrate. A first bonding pad 91 and a second bonding pad 93 spaced apart from each other may be disposed on the package substrate 90. External connection terminals (not shown) respectively connected to the bonding pads 91 and 93 may be disposed outside of the package substrate 90. The bonding pads 91 and 93 and the external connection terminals may be included in a lead frame. The bonding pads 91 and 93 may be or include copper, nickel, or iron pads, etc.

A solder resist layer 95 exposing a portion of the bonding pads 91 and 93 may be disposed on the bonding pads 91 and 93. Bumps 97 and 99 may be formed on the bonding pads 91 and 93, respectively.

The light-emitting diode chip C described with reference to FIGS. 1A to 1G may be formed on the bumps 97 and 99. The first electrode 41 and the second electrode 43 of the light-emitting diode chip C may be respectively connected to the bonding pads 91 and 93 using the bumps 97 and 99.

Light emitted from the active layer 22 of the light-emitting diode chip C may be released through a device substrate 10. A sidewall of the device substrate 10 may have an inclined surface S by which a width of the device substrate 10 decreases toward a rear or bottom surface. In addition, the rear or bottom surface of the device substrate 10 may include uneven patterns 10c. The inclined surface S of the sidewall of the device substrate 10 and the uneven patterns 10c may change a path of light emitted from the active layer 22 or scatter the light to potentially improve light emitting efficiency.

In one implementation, in order to form the uneven patterns 10c on the rear or bottom surface of the device substrate 10 after forming the light-emitting semiconductor layer 20 on a front or top surface of the device substrate 10, a protection layer may need to be formed on the light-emitting semiconductor layer 20. However, as described with reference to FIGS. 1A through 1G, by forming the uneven patterns 10c on the rear or bottom surface of the device substrate 10 before forming the light-emitting semiconductor layer 20, a protection layer may not need to be formed on the light-emitting semiconductor layer 20. Accordingly, fabrication processes may be reduced, which leads to cost saving effects.

In addition, the fluorescent layer 60 may convert light emitted through the device substrate 10 into light having a lower wavelength to implement a white light emitting device. For example, when the light-emitting diode chip C is a device generating ultraviolet light, the white light emitting device may be implemented by arranging a red fluorescent material, a green fluorescent material, and a blue fluorescent material in the fluorescent layer 60. When the light-emitting diode chip C is a device generating blue light, the white light emitting device may be implemented by arranging a yellow fluorescent material in the fluorescent layer 60.

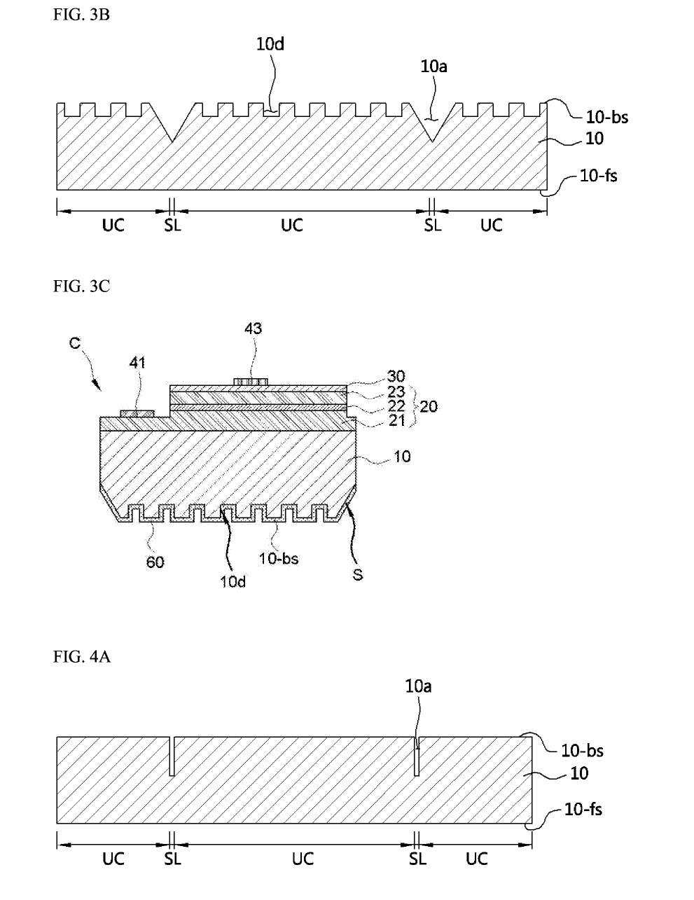

FIGS. 3A to 3C are cross-sectional views showing a method of fabricating a light-emitting diode according to another embodiment of the disclosed technology. The method of fabricating a light-emitting diode according to the embodiment of the disclosed technology is similar to that described with reference to FIGS. 1A to 1G except as disclosed in the following description.

Referring to FIG. 3A, the first mask pattern (reference number 51 in FIG. 1B) may be removed from the rear or bottom surface 10_bs of the substrate 10 including the separating trenches 10a formed by the method described in FIG. 1B. A second mask pattern 53 filling the separating trenches 10a and exposing portions of each light-emitting cell region UC between the separating trenches 10a may be formed on the rear or bottom surface 10_bs of the substrate 10 on which the first mask pattern (reference number 51 in FIG. 1B) has been removed. The second mask pattern 53 may be or include a photoresist pattern.

The rear or bottom surface 10_bs of the substrate 10 may be anisotropically etched, for example, dry-etched using the second mask pattern 53 as a mask. As a result, uneven patterns or concave-convex patterns 10d may be formed in the light-emitting cell regions UC. Concave portions and convex portions of the uneven patterns 10d may have a polygonal shape such as a tetragonal shape.

Referring to FIG. 3B, the second mask pattern 53 may be removed. As a result, the separating trenches 10a having a V-shape whose inlet width is greater than a bottom width, and the uneven patterns 10d having a polygonal shape such as a tetragonal concave portions and convex portions may be exposed on the rear or bottom surface 10_bs of the substrate 10.

Referring to FIG. 3C, a flip-chip light-emitting diode chip C may be obtained through the methods described in FIGS. 1D to 1G. The substrate 10 of the light-emitting diode chip C may taper toward the rear or bottom surface 10_bs of the substrate to have an inclined surface S in a sidewall of the substrate 10. In addition, the rear or bottom surface 10_bs of the substrate 10 may include the uneven patterns 10d. The inclined surface S of the sidewall of the substrate 10 and the uneven patterns 10d may change a path of light emitted from the active layer 22 or scatter the light to potentially improve light emitting efficiency.

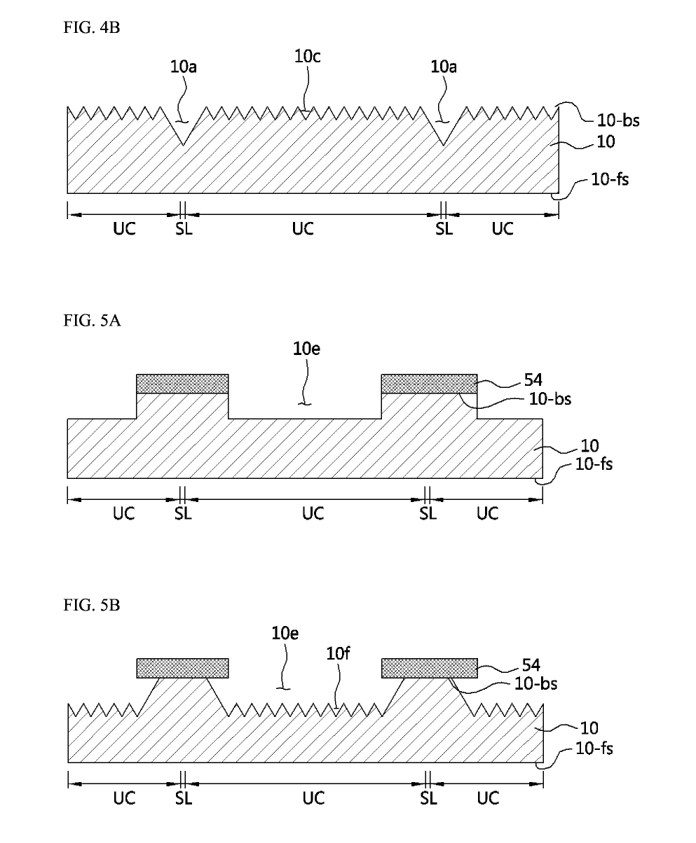

FIGS. 4A and 4B are cross-sectional views showing a method of fabricating a light-emitting diode according to another embodiment of the disclosed technology. The method of fabricating a light-emitting diode according to the embodiment of the disclosed technology is similar to that described with reference to FIGS. 1A to 1G and has differences as discussed in the following description.

Referring to FIG. 4A, separating trenches 10a are formed in separating areas SL of a substrate 10. The separating trenches 10a may be located in a rear or bottom surface 10_bs of the substrate 10. The formation of the separating trenches 10a may be performed by a laser scribing method. Widths of inlets and bottoms of the separating trenches 10a may be substantially the same.

Referring to FIG. 4B, a wet-etching solution may be applied to the surface 10_bs of the substrate 10 in which the separating trenches 10a are formed. As a result, the entire rear or bottom surface 10_bs of the substrate 10 including the separating trenches 10a may be wet-etched. In this process, since side surfaces of the separating trenches 10a are primarily etched compared to bottom surfaces of the separating trenches 10a, the separating trenches 10a may have a V-shape whose inlet width is greater than a bottom width. At the same time, uneven patterns or concave-convex patterns 10c may be formed in light-emitting cell regions UC of the rear or bottom surface 10_bs. The wet-etching solution may be or include a sulfate-phosphate mixed solution or a KOH solution. The wet-etching solution may be or include a heated solution.

Next, a flip-chip light-emitting diode chip C may be obtained through the methods described in FIGS. 1D to 1G.

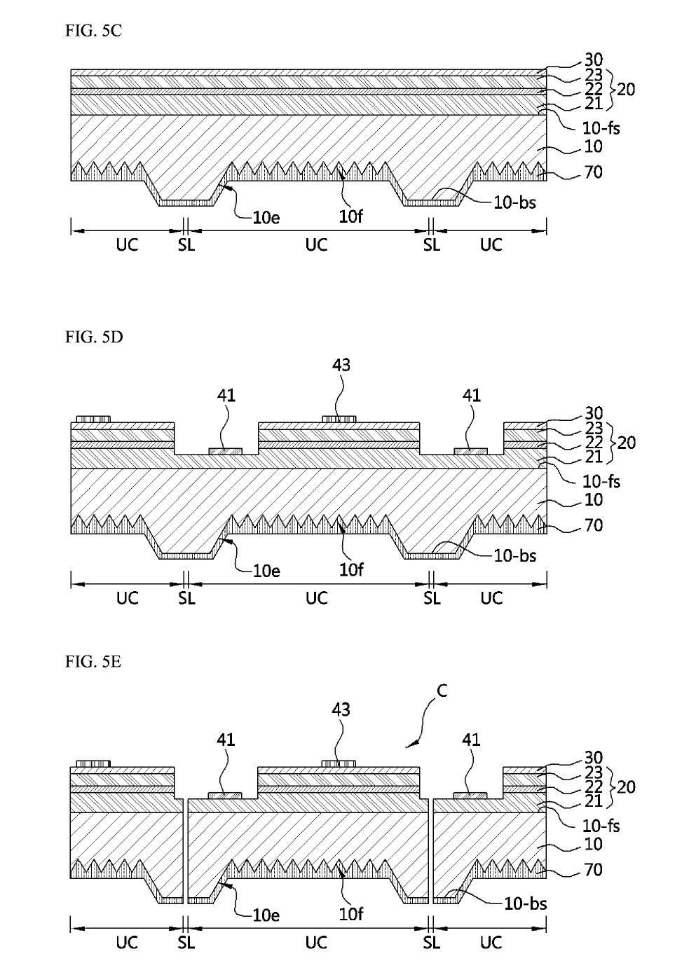

FIGS. 5A to 5E are cross-sectional views showing a method of fabricating a light-emitting diode according to another embodiment of the disclosed technology. The method of fabricating a light-emitting diode according to the embodiment of the disclosed technology is similar to that described with reference to FIGS. 1A to 1G except as disclosed in the following description.

Referring to FIG. 5A, a substrate 10 may be provided. The substrate 10 includes a plurality of light-emitting cell regions UC and separating areas SL located between the light-emitting cell regions UC. In addition, the substrate 10 includes a front or top surface 10_fs and a rear or bottom surface 10_bs.

A mask pattern 54 may be formed on the rear or bottom surface 10_bs. The mask pattern 54 may be or include a photoresist pattern. The mask pattern 54 may be located on the separating areas SL and extended to areas adjacent to the separating areas SL. The central portions of the light-emitting cell regions UC may be exposed by the mask pattern 54. Trenches 10e may be formed in the light-emitting cell regions UC exposed by the mask pattern 54. The formation of the trenches 10e may be performed by an anisotropic etching method, for example, a dry-etching method. Widths of inlets and bottoms of the trenches 10e may be substantially the same.

Referring to FIG. 5B, a wet-etching solution may be applied to the rear surface 10_bs of the substrate 10 in which the trenches 10e are formed. As a result, the rear or bottom surface 10_bs of the substrate 10 may be wet-etched using the mask pattern 54 as a mask. In this process, uneven patterns or concave-convex patterns 10f may be formed on bottom surfaces of the trenches 10e. Concave portions of the uneven patterns 10f may have a V-shape. At the same time, since side surfaces of the trenches 10e are primarily etched compared to the bottom surfaces of the trenches 10e, the trenches 10e may have a V-shape such that inlet width of the trenches 10e is greater than a bottom width of the trenches 10e. The wet-etching solution may be or include a sulfate-phosphate mixed solution or a KOH solution. The wet-etching solution may be or include a heated solution.

Referring to FIG. 5C, the mask pattern 54 may be removed to expose relatively flat surface of rear or bottom surface 10_bs. A first conductivity-type semiconductor layer 21, an active layer 22, and a second conductivity-type semiconductor layer 23 may be formed on the front or top surface 10_fs of the substrate 10. The first conductivity-type semiconductor layer 21, the active layer 22, and the second conductivity-type semiconductor layer 23 may configure a light-emitting semiconductor layer 20. The light-emitting semiconductor layer 20 may be formed using an MOCVD method or an MBE method. A current spreading conductive layer 30 may be formed on the light-emitting semiconductor layer 20. The current spreading conductive layer 30 may be or include a transparent conductive layer, such as an ITO layer.

Next, a reflective layer 70 may be formed on the rear or bottom surface 10_bs of the substrate 10. The reflective layer 70 may be or include a metal layer, such as Ag and Al, a distributed Bragg reflector (DBR), or an omni-directional reflector (ODR).

Referring to FIG. 5D, the current spreading conductive layer 30, the second conductivity-type semiconductor layer 23, and the active layer 22 are mesa-etched to expose the first conductivity-type semiconductor layer 21. A first electrode 41 and a second electrode 43 may be formed on the exposed first conductivity-type semiconductor layer 21 and the current spreading conductive layer 30, respectively.

Referring to FIG. 5E, light-emitting cells are separated by scribing and cutting the separating areas SL. Each of the separated light-emitting cells may form a light-emitting diode chip C. Light generated in the active layer 22 of the light-emitting diode chip C may be emitted up away from the substrate 10 rather than down towards the substrate 10. A portion of light may propagate from the active layer 22 to substrate 10. In this case, light propagated from the active layer 22 may be reflected by the reflective layer 70 so that the reflected light emits in an upward direction. In addition, a thickness of substrate 10 may be lowered in a central portion of the light-emitting diode chip C by forming the trenches 10e in the substrate rear or bottom surface 10_bs. As a result, a path of the light propagating from the active layer 22 toward the substrate 10 and then reflected by the reflective layer 70 may be reduced. In addition, the uneven patterns 10f formed in the bottom surfaces of the trenches 10e may scatter the light. In this way, light emission efficiency can be significantly improved due to the reflective layer 70, the trenches 10e, and the uneven patterns 10f.

According to embodiments of this patent document, light extraction efficiency can be improved by forming uneven patterns on a rear or bottom surface of a substrate. Meanwhile, in order to form the uneven patterns on the rear or bottom surface of the substrate after forming a light-emitting semiconductor layer on a front or top surface of the substrate, a protection layer may ordinarily be needed to be formed on the light-emitting semiconductor layer. However, according to embodiments of this patent document, since the uneven patterns are formed on the rear or bottom surface of the substrate before forming the light-emitting semiconductor layer, the protection layer may not need to be formed. Accordingly, fabrication processes may be reduced, which leads to cost saving effects.

Although a few embodiments have been described, it will be apparent to those skilled in the art that various modifications can be made to the above-described exemplary embodiments of this patent document without departing from the spirit or scope of the invention.

1. A method of fabricating a light-emitting diode, comprising:
providing a substrate having a front surface and a rear surface;
forming uneven patterns in the rear surface of the substrate;
forming a light-emitting semiconductor layer by stacking a first-type semiconductor layer, an active layer, and a second-type semiconductor layer over the front surface of the substrate having the uneven patterns in the rear surface; and
separating the light-emitting semiconductor layer and the substrate into a plurality of light-emitting cells.

2. The method of claim 1,
wherein the substrate has a plurality of light-emitting cell regions and a separating area located between the light-emitting cell regions, and
the forming of the uneven patterns comprises:
forming a separating trench whose inlet width is greater than a bottom width of the trench in the separating area and areas adjacent to the separating area; and
forming the uneven patterns in the light-emitting cell regions.

3. The method of claim 2, further comprising:
before the forming of the separating trench, forming a first mask pattern to expose the separating area and the areas adjacent to the separating areas on the rear surface of the substrate and laser-scribing the separating area in which the separating trench is to be formed,
wherein the forming of the separating trench includes wet-etching on the rear surface of the laser-scribed substrate using the first mask pattern as a mask.

4. The method of claim 3, further comprising:
forming a second mask pattern to fill the separating trench,
wherein the forming of the uneven patterns includes wet-etching on the rear surface of the substrate using the second mask pattern as a mask.

5. The method of claim 3, further comprising:
forming a second mask pattern to fill the separating trench and expose portions of each light-emitting cell region,
wherein the forming of the uneven patterns includes dry-etching on the rear surface of the substrate using the second mask pattern as a mask.

6. The method of claim 2, further comprising:
laser-scribing the separating area before forming the separating trench,
wherein the forming of the separating trenches and the forming of the uneven pattern are simultaneously performed by wet-etching of the rear surface of the laser-scribed substrate.

7. The method of claim 1, further comprising:
forming a fluorescent material layer on the uneven pattern before separating the light-emitting semiconductor layer and the substrate into the plurality of light-emitting cells.

8. The method of claim 1, wherein the substrate has light-emitting cell regions and a separating area located between light emitting cell regions, and the method further comprising:
before forming the uneven patterns, forming a first mask pattern on the separating area and the areas adjacent to the separating areas, and forming a trench in the rear surface by etching the rear surface using the first mask pattern as a mask,
wherein the uneven patterns are formed in a bottom surface of the trench.

9. The method of claim 8, further comprising:
forming a reflective layer on the uneven pattern before separating the light-emitting semiconductor layer and the substrate into the plurality of light-emitting cells.

10. A light-emitting diode, comprising:
a substrate having a front surface and a rear surface;
uneven patterns formed in the rear surface of the substrate; and
a first-type semiconductor layer, an active layer, and a second-type semiconductor layer stacked on the front surface of the substrate.

11. The light-emitting diode of claim 10, wherein a sidewall of the substrate includes an inclined surface such that the substrate has a smaller width at the rear surface than the front surface.

12. The light-emitting diode of claim 10, further comprising a fluorescent material layer disposed on the uneven patterns.

13. The light-emitting diode of claim 10, wherein the substrate includes a trench in the rear surface, and
the uneven patterns are located in a bottom surface of the trench.

14. The light-emitting diode of claim 13, further comprising a reflective layer disposed on the uneven patterns.

15. A light-emitting device comprising:
a substrate having a first surface disposed to form uneven patterns and a second surface substantially opposite to the first surface, wherein the substrate is disposed to form an inclined sidewall such that a width of the substrate at the first surface is smaller than at the second surface;
a first-type semiconductor layer, an active layer, and a second-type semiconductor layer stacked over the second surface of the substrate,
wherein the uneven patterns and the inclined sidewall of the substrate are structured to allow light emitted from the active layer towards the first surface of the substrate to change one or more optical properties.

16. The light-emitting device of claim 15, wherein the uneven patterns have a V shape or polygonal shape.

17. The light-emitting device of claim 15, comprising:
a fluorescent material layer is disposed on the uneven patterns of the first surface of the substrate.

18. The light-emitting device of claim 15, wherein the first surface of the substrate is disposed to form a trench having uneven patterns on a bottom surface of the trench.
